(19) United States
(12) Patent Application Publication
(10) Pub. No.: US 2024/0162361 A1
(43) Pub. Date: May 16, 2024

(54) ANTIREFLECTIVE STRUCTURES FOR COVER GLASSES IN SINGLE OR MULTIJUNCTION SOLAR CELLS

(71) Applicant: SolAero Technologies Corp., Albuquerque, NM (US)

(72) Inventor: Daniel Derkacs, Albuquerque, NM (US)

(21) Appl. No.: 18/056,161

(22) Filed: Nov. 16, 2022

(51) Int. Cl. H01L 31/054; H01L 31/0236; H01L 31/048; H01L 31/052; H01L 31/18

(52) U.S. Cl. CPC H01L 31/0543; H01L 31/0236; H01L 31/0481; H01L 31/052; H01L 31/18

(57) ABSTRACT

A cover glass for use in connection with a multijunction solar cell, and its method of fabrication, the solar cell including an upper and a lower solar subcell, each having an emitter layer and a base layer and forming a photoelectric junction; the cover glass being disposed above the upper solar subcell for transmitting light in the spectral range of a wavelength of 5 to 50 nm which represents unused and undesired heat energy and thereby providing thermodynamic radiative cooling of the solar cell when deployed in space outside the atmosphere.

### REFERENCE TO RELATED APPLICATIONS

This application is related to U.S. patent application Ser. No. 14/216,607 filed Mar. 17, 2014, now U.S. Pat. No. 10,153,388.

This application is also related to co-pending U.S. patent application Ser. No. 15/449,590 filed Mar. 3, 2017 now U.S. Pat. No. 10,479,053.

This application is also related to U.S. patent application Ser. No. 17/191,355 filed Mar. 3, 2021, now U.S. Pat. No. 11,329,181.

All of the above related applications are incorporated herein by reference in their entirety.

### BACKGROUND OF THE INVENTION

### Field of the Invention

The present disclosure relates to cover glasses used over single or multijunction solar cells for space applications and the fabrication of such cover glasses, and more particularly the design and specification of and reflective structures on such cover glasses.

### Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to properly specify and manufacture. Typical commercial III-V compound semiconductor multijunction solar cells have energy efficiencies that exceed 27% under one sun, air mass 0 (AMO) illumination, whereas even the most efficient silicon technologies generally reach only about 18% efficiency under comparable conditions. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, and applications anticipated for five, ten, twenty or more years, the power-to-weight ratio and lifetime efficiency of a solar cell becomes increasingly more important, and there is increasing interest not only the amount of power provided at initial deployment, but over the entire service life of the satellite system, or in terms of a design specification, the amount of power provided at the “end of life” (EOL).

Typical III-V compound semiconductor solar cells are fabricated on a semiconductor wafer in vertical, multijunction structures or stacked sequence of solar subcells, each subcell formed with appropriate semiconductor layers and including a p-n photoactive junction. Each subcell is designed to convert photons over different spectral or wavelength bands to electrical current. After the sunlight impinges on the front of the solar cell, and photons pass through the subcells, with each subcell being designed for photons in a specific wavelength band. After passing through a subcell, the photons that are not absorbed and converted to electrical energy propagate to the next subcells, where such photons are intended to be captured and converted to electrical energy.

The energy conversion efficiency of multijunction solar cells is affected by such factors as the number of subcells, the thickness of each subcell, the composition and doping of each active layer in a subcell, and the consequential band structure, electron energy levels, conduction, and absorption of each subcell, as well as the effect of its exposure to radiation in the ambient environment over time. The identification and specification of such design parameters is a non-trivial engineering undertaking, and would vary depending upon the specific space mission and customer design requirements. Since the power output is a function of both the voltage and the current produced by a subcell, a simplistic view may seek to maximize both parameters in a subcell by increasing a constituent element, or the doping level, to achieve that effect. However, in reality, changing a material parameter that increases the voltage may result in a decrease in current, and therefore a lower power output. Such material design parameters are interdependent and interact in complex and often unpredictable ways, and for that reason are not “result effective” variables that those skilled in the art confronted with complex design specifications and practical operational considerations can easily adjust to optimize performance. Electrical properties such as the short circuit current density (J_{sc}), the open circuit voltage (V_{oc}), and the fill factor (FF), which determine the efficiency and power output of the solar cell, are affected by the slightest change in such design variables, and as noted above, to further complicate the calculus, such variables and resulting properties also vary, in a non-uniform manner, over time (i.e. during the operational life of the system).

The operational condition of solar cells is satellite and other apace operations are extreme and dictate design features for space solar cells that are not needed in terrestrial applications. For example, the temperature ranges and temperature cycles encountered in space vary from −175° C. to +180° C.

The band gap of a semiconductor decreases with temperature. For example, GaAs will have a bang gap of 1.44 eV at 0° C. but 1.376 eV at 126° C. A drop in band gap will result in a drop in voltage in the subcell, and therefore a decrease in the power output of the solar cell. As a result, there is increase interest in providing means for keeping the solar cells as cool as possible by increasing the emissivity of the surroundings elements supporting or framing the solar cells.

A space solar cell often includes a cover glass over the semiconductor device to provide radiation resistant shielding from particles in the space environment which could damage the semiconductor material. The cover glass is typically a ceria doped borosilicate glass which is typically from three to six mils in thickness and attached by a transparent adhesive to the solar cell.

The assembly of individual solar cells together with electrical interconnects and the cover glass form a so-called “CIC” (Cell-Interconnected-Cover glass) assembly. Which are then typically electrically connected to form an array of series-connected solar cells. The solar cells used in many arrays often have a substantial size; for example, in the case of the single standard substantially “square” solar cell trimmed from 100 mm wafer with cropped corners, the solar cell can have a side length of seven cm or more.

In summary, it is evident that the differences in design, materials, and configurations between a space-qualified III-V compound semiconductor solar cell and assemblies and arrays of such solar cells, on the one hand, and silicon solar cells or other photovoltaic devices used in terrestrial applications, on the other hand, are so substantial that prior teachings associated with silicon or other terrestrial photovoltaic system are simply unsuitable and have no applicability to the design configuration of space-qualified solar cells and arrays. Indeed, the design and configuration of components adapted for terrestrial use with its modest temperature ranges and cycle times often teach away from the highly demanding design requirements for space-qualified solar cells and arrays and their associated components.

The present disclosure proposes design features for solar cells and solar cell assemblies for increasing the efficiency of the solar cell in converting solar energy to electrical energy in a space environment.

### SUMMARY OF THE DISCLOSURE

### Objects of the Disclosure

It is an object of the present disclosure to provide increased photoconversion efficiency in a solar cell assembly for space applications by incorporating a structure on the upper surface of the cover glass disposed over the single or multijunction solar cell so as to increase the emissivity of the cover glass and more effectively radiate the heat absorbed by the solar cell.

Is another object of the present disclosure to provide increased photoconversion efficiency in a solar cell for space applications by incorporating a retroreflector surface structure mounted over the solar cell.

It is another object of the present disclosure to increase the thermodynamic radiative cooling of the solar cell when deployed in space outside the atmosphere through employing a cover glass over the solar cell with improved emissivity.

It is another object of the present disclosure to increase the thermodynamic radiative cooling of the solar cell when deployed in space outside the atmosphere through employing a cover glass over the solar cell changes and minimizes the reststrahlen effect associated with the use of the cover glass effect to improve emissivity.

Is another object of the present disclosure to provide a cover glass having an array of geometrical structures on the surface structure thereof to enable the radiative cooling of the active element disposed between the cover glass.

Is another object of the present disclosure to provide a cover glass in having an array of geometrical structures on the surface structure thereof that minimizes the reststrahlen effect to enable the radiative cooling of the active element disposed between the cover glass.

Is an object of the present disclosure to provide a single or multijunction solar cell in which the placement of a cover glass in which the cell heats the glass via conduction through silicone, glass emits heat via front surface of glass with a high emissivity surface enables the emission of a greater amount of heat than the use of a cover glass without such a high emissivity surface.

Some implementations of the present disclosure may incorporate or implement fewer of the aspects and features noted in the foregoing objects.

### Features of the Disclosure

All ranges of numerical parameters set forth in this disclosure are to be understood to encompass any and all subranges or “intermediate generalizations” subsumed herein. For example, a stated range of 5 to 50 microns for a value should be considered to include any and all subranges beginning with a minimum value of 5 microns or more and ending with a maximum value of 50 microns les, e.g., 5 to 10 microns, or 10 to 30 microns, or 45 to 20 microns.

Briefly, and in general terms, the present disclosure provides cover glass for placement over the top surface of a solar cell comprising a body composed of glass disposed adjacent to the solar cell and an array of geometrical structures disposed adjacent to one another on the top surface of the body each geometrical structure including a base and apex and forming a plurality of vias between the geometrical structures, wherein the geometrical structures are sized and shaped to increase the transmissivity of infrared radiation in a wavelength range of 5 to 50 microns from the solar cell into the adjoining environment.

In some embodiments, the array of geometrical structures are sized and shaped so as to change the index of refraction and thereby increase the IR emissivity and corresponding IR transmissivity of the top surface of the body, and thereby reduce the retention of heat in the body caused by the radiative transfer of heat generated in the solar cell during its illumination and operation.

In some embodiments the geometric structure has a base, a width and a height, and wherein the ratio between the width of the base and the height of the geometric structure is in the range of 1:1 to 1:6.

In some embodiments, the array of geometrical structures also has the property that the reflectivity of the cover glass in the wavelength range of 300 nm to 2000 nm in maintained or lowered.

In some embodiments a height of the geometrical structure is in the range of 5 to 300 microns.

In some embodiments a pitch of the array of the geometrical structures is in the range of 5 to 50 microns.

In some embodiments the base and the apex of the geometrical structure are connected by a single planar surface.

In some embodiments the base and the apex of the geometrical structure are connected by a first and a second surface, the first surface being adjacent to the base and the second surface being adjacent to the apex.

In some embodiments, at least one of the first and second surfaces are planar or flat.

In some embodiments the second surface is at least twice the area of the first surface.

In some embodiments the base and the apex are connected by two truncated cone shaped bodies.

In some embodiments the base is circular or polygonal in shape.

In some embodiments the apex of the geometrical structures is a substantially planar surface which is smaller than the base.

In some embodiments, the geometrical structures are surface perturbations on the cover glass.

In some embodiments the glass is a cerium borosilicate glass which is doped.

In some embodiments the thickness of the body of glass is approximately 150 microns.

In another aspect, the present disclosure provides a method comprising: providing a solar cell; providing a body composed of glass comprising a top surface configurated to receive solar radiation, and a bottom surface configured to be disposed over the solar cell; and laser etching the top surface of the glass to form an array of geometrical structures disposed adjacent to another on the top surface of the body each geometrical structure including a base and an apex and forming a plurality of vias between the geometrical structures, wherein the geometrical structures are sized and shaped to increase emissivity (or equally reduce reflectivity) of infrared radiation from the solar cell through the body in a wavelength range of 5 to 50 microns from the solar cell into the adjoining environment (since the glass is very opaque to IR over 5-50 um, the thermal conduction allows the heat of the solar cell to warm the glass and the glass surface, and the surface of the cover glass emits radiation to cold space. In another aspect, the present disclosure provides a cover glass for placement over the top surface of a solar cell comprising: a body composed of glass disposed adjacent to the solar cell; and an array of geometrical structures disposed on the light receiving or top surface of the body, each structure including a base and an apex and being disposed adjacent to one another and forming a plurality of vias on the top surface of the body that are sized and shaped to efficiently absorb and re-emit incoming light in the wavelength range of 5 to 50 microns so as to change the index of refraction and thereby increase the IR emissivity and corresponding reduce the IR reflectivity of the top surface of the body, and thereby reduce the retention of heat in the body caused by the conductive transfer of heat generated in the solar cell during the illumination and operation of the solar cell.

In another aspect, the present disclosure provides a method of fabricating a cover glass for bonding over the top surface of a single or multijunction solar cell comprising: providing a body composed of glass; laser etching an array of geometrical structures have a base width between 5 to 50 microns and disposed on the light receiving or top surface of the body, each structure including a base and an apex and being disposed adjacent to one another and forming a plurality of vias on the top surface of the body; and bonding the glass body to the top surface of the single or multijunction solar cell.

In some embodiments, the solar cell is an III-V compound semiconductor multijunction solar cell.

In some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure as disclosed and claimed herein and with respect to which the disclosure could be of utility.

### BRIEF DESCRIPTION OF THE DRAWINGS

The disclosure will be better and more fully appreciated by reference to the following detailed description when considered in conjunction with the accompanying drawings, wherein:

FIG. 1 depicts a CIC including two solar cell mosaic portions according to the present disclosure;

FIGS. 2A, 2B and 2C are highly simplified cross-sectional views of the top surface portion of a variety of different cover glasses with surface treatments or structures according to the present disclosure;

FIG. 3 is a graph that depicts the reflectivity of the surface of a cover glass having the composition of these used in fabricating a CIC;

FIG. 4A illustrates an array of cones in one embodiment of the geometrical structure implemented on the cover glass according to the present disclosure;

FIG. 4B illustrates an array of pyramids on the surface according to the present disclosure;

FIG. 5A is a graph depicting (i) the change in temperature of a cover glass as a function of the hemispherical emissivity through the top surface of the cover glass, and (ii) the corresponding solar cell efficiency for a typical triple-junction solar cell mounted in a CIC with the cover glass having the hemispherical emissivities shown on the x-axis and the corresponding temperature of the CIC assembly shown on the y-axis, and

FIG. 5B is a graph similar to that of FIG. 5A but calibrated with respect to temperature of a CIC in operation a GEO orbit.

### DESCRIPTION OF THE EMBODIMENTS

Details of the present invention will now be described including exemplary aspects and embodiments thereof. Referring to the drawings and the following description, like reference numbers are used to identify like or functionally similar elements, and are intended to illustrate major features of exemplary embodiments in highly simplified diagrammatic manner. Moreover, the drawings are not intended to depict every feature of the actual embodiment nor the relative dimensions of the depicted elements, and are not to scale.

Reference through this specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout this specification are not necessarily all referring to the same embodiment. Furthermore, the particular features, structures, or characteristics may be combined in any manner in one or more embodiments.

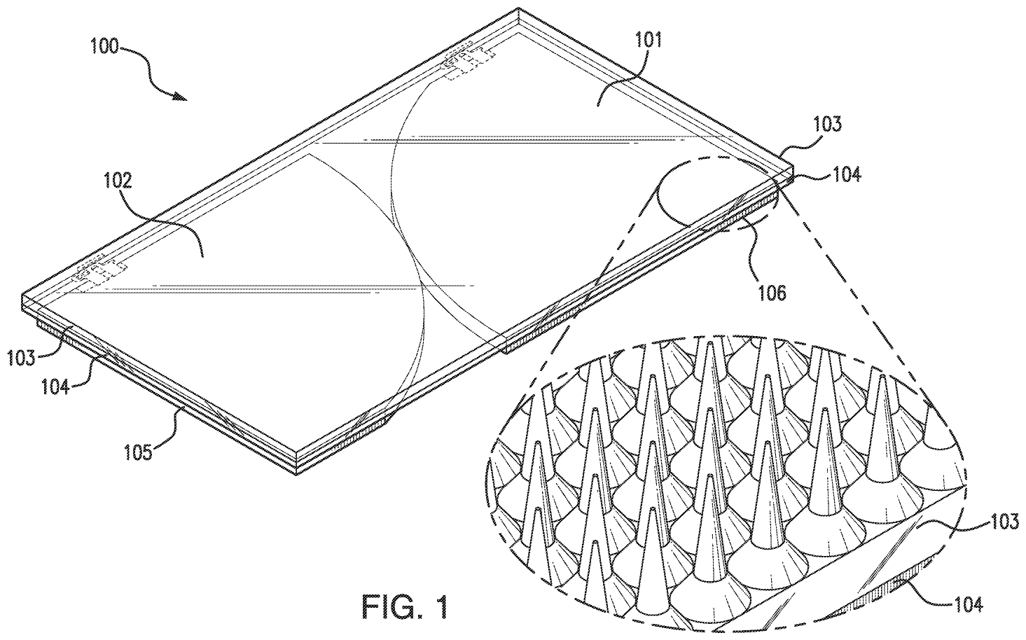

FIG. 1 depicts a CIC 100 including two solar cell mosaic portions 101/105 and 102/105 with an adhesive 104 on the top surface thereof bonded to cover glass 103. In some embodiments a single solar cell may be arranged under the cover glass 103, and in other embodiments a plurality of solar cell mosaic portions may be positioned, aligned and arranged under the single cover glass 103.

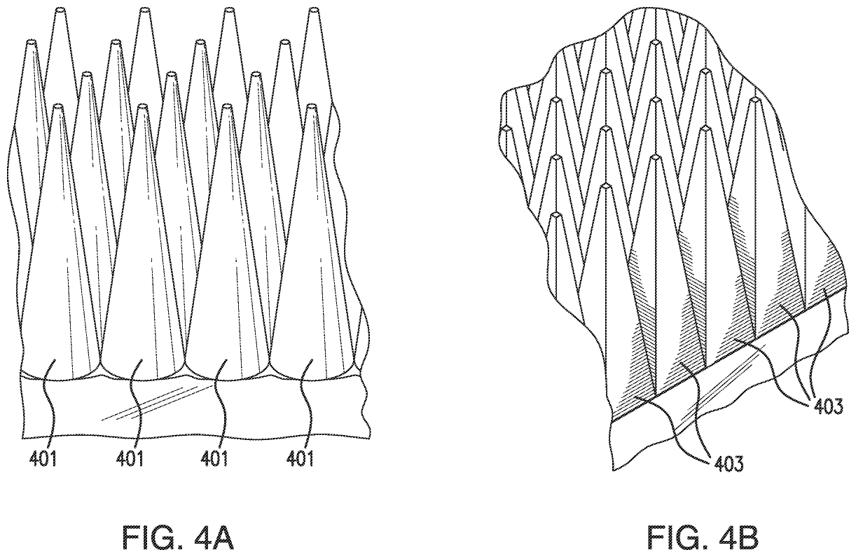

The call-out on the lower right-hand side of FIG. 1 depicts a highly enlarged top surface view of the cover glass 103 illustrating an array of geometrical structures 107 according to the present disclosure. Although the embodiment specifically illustrated is a conical structure, the geometrical structure may be a pyramid with any polygonal base such as a square or hexagonal, or any other pillar type structure having a base 108 and an apex, 109, with the diameter of the structure decreasing from the base to the apex either continuously or incrementally in one or more steps to a different slope. Examples of other embodiments of the geometrical structure is shown in FIGS. 4A and 4B below. The previous disclosure is not limited to the specific structure shown, but may be any structure that provides the change in refractive index conventionally designated.

Although in the depicted embodiment all of the geometrical structures in the array are identical in size and shape, in other embodiments the shape may be different, the size may be different, or both the size and the shape may differ of the various structures within the array.

In some embodiments, the width of the base may be in the approximate range of 5 to 50 microns. That ratio of the width of the base to the height may range from 1:1 to 1:6, so correspondingly the height of each of the geometrical structures may be in the range of 5 to 300 microns.

In one embodiment, the width of the base is approximately 20 microns, and the ratio of the width of the base to the height is 1:3. In other embodiments, the width of the base may be 10 microns, 15 microns, 25 microns, or 30 microns.

The apex of each of the geometrical structures may be a point or a small flat surface. The structure area of the flat surface may be 2%, 5%, or 7% of the area of the base, or any value between_0_% and_10_%.

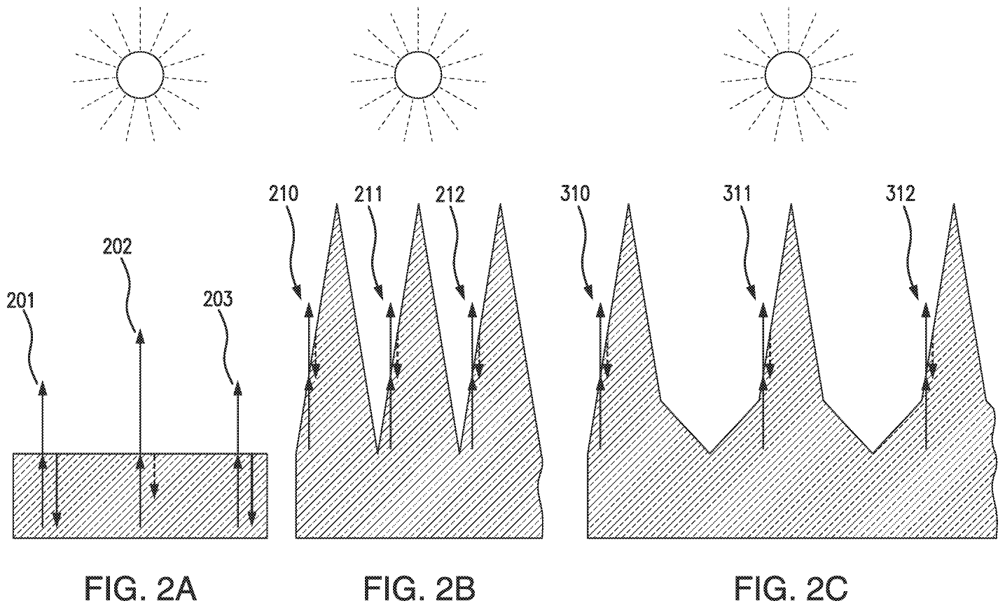

FIGS. 2A, B and 2C are highly simplified cross-sectional views of the top surface portion of a variety of different cover glasses to illustrate the reflectivity of the top surface when IR radiation is emitted of different wavelengths arising from the interior temperature of the cover glass. As we noted above, where the CIC assembly is employed in a photovoltaic panel in space and illuminated by the incident sunlight, the individual solar cells produce heat as a byproduct of being less than 100% efficient in converting photons to electricity. The heat generated results in the solar cell typically attaining an operating temperature of between 50° and 70° C. in when deployed low earth orbit (LEO) of between 200 and 1000 km from the surface of the earth, and between 30° and 40° C. when deployed in geospatial space orbit (GEO) of approximately 36,000 km. from the surface of the earth. The generated heat is conductively transferred to the bonded cover glass mounted over the top surface of the solar cell, and the temperature of the cover glass correspondingly rises and is radiatively transferred to the adjacent space environment:

An understanding of the black body IR radiation in a broad-spectrum range and the effect of surface features (or lack thereof) of the cover glass is necessary at this point. FIG. 2A illustrates the reflectivity of the top surface of a cover glass at three different IR spectral wavelengths.

The arrows associated with reference number 201 depict the transmission of certain IR radiation through the surface of the cover glass, and the reflection of a portion of that IR radiation back into the glass. The length of the arrows in this and subsequent Figures represent the magnitude of the associated radiation in a highly simplified and diagrammatic manner (need to review this figure). In the example depicted by the arrow in 201, the radiation wavelength is approximately 9 microns. The numeric value of the wavelength being selected to depict the transmission of radiation is purely for illustrative purposes.

Reference number 202 depicts the radiative transfer and reflectivity associated with radiation with a wavelength of microns. Compared with 201, it is evident that the reflectivity at the surface is much less than that of 201, and thus a greater amount of IR radiation, and therefore heat, is transmitted/emitted into space.

As noted above, the efficiency of a solar cell is directly related to its operating temperature. The lower the operating temperature, the greater the efficiency. Since as noted in the examples of 201, 202 and 203 IR radiation wavelength, the reflectivity of the glass empirically varies depending upon the incident wavelength of the radiation due to the inherent compositional features of the glass that are typically used in space applications. Applicant's attention was therefore directed to examining the effect of surface features of the cover glass which may change the reflectivity at specific identified wavelengths, therefore increase the amount of IR radiation associated with these wavelengths, and corresponding by reduce the operating temperature of the CIC by allowing greater radiative transfer of heat.

A variety of geometrical structures implemented on the surface of the cover glass can affect the IR reflectivity at the surface, as illustrated with the highly simplified examples of FIGS. 2B and 2C which illustrate in FIG. 2B a simple cone and in FIG. 2C a two step cone with planar surfaces at different angles or slopes with respect the base.

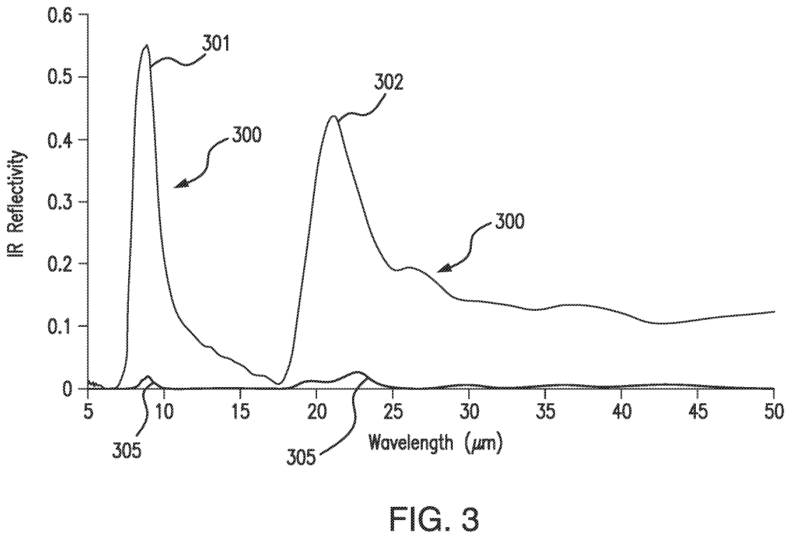

An examination of the length of the arrows depicted in FIGS. 2B and 2C illustrates the effect of the reflectivity (and corresponding transmissivity through the surface) that is relatively uniform over the wavelength spectrum under consideration. Numerically, rather than an IR reflectivity of 30%, 40%, 50% or more, depending upon wavelength, the IR reflectivity though the surface of the cover glass may be reduced to nearly 0%, as will be subsequently illustrated in FIG. 3.

One of the characteristics features of the geometric structures according to the present disclosure is that the dimensions of the various structures, including the pitch between individual structural elements, or the depth of the vias separating the structural elements, is numerically approximately that of the wavelength value of IR radiation at issue.

FIG. 3 is a graph that depicts the reflectivity of the surface of a cover glass having the composition of these used in fabricating a CIC used for space applications once a broad wavelength spectrum from 5 to 50 microns typical of IR radiation conducted through the glass and emitted to the external environment. The first curve 300 represents the IR reflectivity of a flat, planar cover glass as currently commercially used for CICs in space applications. The peaks 301 and 302 of high IR reflectivity of over 40% centered around wavelength of 9 microns and 22 microns are notable. The second curve 305 represents the IR reflectivity of a cover glass having the same composition but having an array of geometrical structures according to the present disclosure implemented on the top surface of the cover glass. The substantially lower IR reflectivity through the entire broad wavelength range is notable.

FIG. 4A illustrates an array of cones 401 at the geometrical structure implemented on the surface of the cover glass and FIG. 4B an array of pyramids 403 on the surface according to the present disclosure.

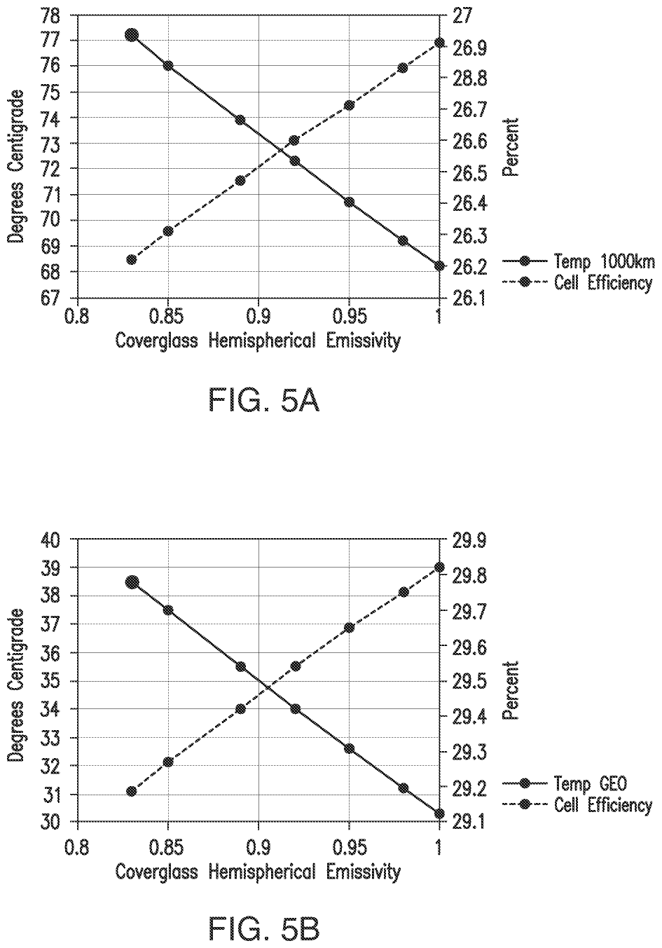

FIG. 5A is a graph depicting (i) the change in temperature of a cover glass as a function of the hemispherical emissivity through the top surface of the cover glass, and (ii) the corresponding solar cell efficiency for a typical triple-junction solar cell mounted in a CIC with the cover glass having the hemispherical emissivities shown on the x-axis and the corresponding temperature of the CIC assembly shown on the y-axis. It is noted that being able to lower the temperature from 77° C. to 68° C. (associated with a 1000 km LEO orbit) results in an improvement in efficiency from 26.2% to 26.9%.

FIG. 5B is a graph similar to that of FIG. 5A but calibrated with respect to temperature of CIC in GEO orbit, depicted on the y-axis from 30 to 39° C. The corresponding ability of the cover glass according to the present disclosure to lower the temperature from 39° C. to 31° C. results in an improvement in efficiency from 29.2% to 29.8%.

The vias also maintain or even lower the visible reflectivity of the glass from 300 nm-2000 nm. This is a critical feature in that one can design a structure or layers of materials that reduce the reflectance in the IR but severely increase the reflectivity of the glass in the visible light range.

It will be understood that each of the elements described above, or two or more together, also may find a useful application in other types of structures or constructions differing from the types of structures or constructions described above.

The terminology used in this disclosure is for the purpose of describing specific identified embodiments only and is not intended to be limiting of different examples or embodiments.

In the drawings, the position, relative distance, lengths, widths, and thicknesses of supports, substrates, layers, regions, films, etc., may be exaggerated for presentation simplicity or clarity. Like reference numerals designate like elements throughout the specification. It will be understood that when an element such as an element layer, film, region, or feature is referred to as being “on” another element, it can be disposed directly on the other element or the presence of intervening elements may also be possible. In contrast, when an element is referred to as being disposed “directly on” another element, there are no intervening elements present.

Furthermore, those skilled in the art will recognize that boundaries and spacings between the above described units/operations are merely illustrative. The multiple units/operations may be combined into a single unit/operation, a single unit/operation may be distributed in additional units/operations, and units/operations may be operated at least partially overlapping in time. Moreover, alternative embodiments may include multiple instances of a particular unit/operation, and the order of operations may be altered in various other embodiments.

The terms “substantially”, “essentially”, “approximately”, “about”, or any other similar expression relating to particular parametric numerical value are defined as being close to that value as understood by one of ordinary skill in the art in the context of that parameter, and in one non-limiting embodiment the term is defined to be within 10% of that value, in another embodiment within 5% of that value, in another embodiment within 1% of that value, and in another embodiment within 0.5% of that value.

The term “coupled” as used herein is defined as connected, although not necessarily directly or physically adjoining, and not necessarily structurally or mechanically. A device or structure that is “configured” in a certain way is arranged or configured in at least that described way, but may also be arranged or configured in ways that are not described or depicted.

The terms “front”, “back”, “side”, “top”, “bottom”, “over”, “on”, “above”, “beneath”, “below”, “under”, and the like in the description and the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein. For example, if the assembly in the figures is inverted or turned over, elements of the assembly described as “below” or “beneath” other elements or features would then be oriented “above” the other elements or features. Thus, the exemplary term “below” can encompass both an orientation of above and below. The assembly may be otherwise oriented (rotated by a number of degrees through an axis).

The terms “front side” and “backside” refer to the final arrangement of the panel, integrated cell structure or of the individual solar cells with respect to the illumination or incoming light incidence.

In the claims, the word ‘comprising’ or ‘having’ does not exclude the presence of other elements or steps than those listed in a claim. It is understood that the terms “comprises”, “comprising”, “includes”, and “including” if used herein, specify the presence of stated components, elements, features, steps, or operations, components, but do not preclude the presence or addition of one or more other components, elements, features, steps, or operations, or combinations and permutations thereof.

The terms “a” or” an“, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the claim includes the introductory phrases “one or more” or “at least one” and indefinite articles such as “a” or “an”. The same holds true for the use of definite articles.

The present disclosure can be embodied in various ways. To the extent a sequence of steps are described, the above described orders of the steps for the methods are only intended to be illustrative, and the steps of the methods of the present disclosure are not limited to the above specifically described orders unless otherwise specifically stated. Note that the embodiments of the present disclosure can be freely combined with each other without departing from the spirit and scope of the disclosure.

Although some specific embodiments of the present disclosure have been demonstrated in detail with examples, it should be understood by a person skilled in the art that the above examples are only intended to be illustrative but not to limit the scope and spirit of the present disclosure. The above embodiments can be modified without departing from the scope and spirit of the present disclosure which are to be defined by the attached claims. Accordingly, other implementations are within the scope of the claims.

Although described embodiments of the present disclosure utilizes a vertical stack of a certain illustrated number of subcells, various aspects and features of the present disclosure can apply to stacks with fewer or greater number of subcells, i.e. two junction cells, three junction cells, four, five, six, seven junction cells, etc.

In addition, although the disclosed embodiments are configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the solar cell described in the present disclosure may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell C, with p-type and n-type InGaAs is one example of a homojunction subcell.

In some cells, a thin so-called “intrinsic layer” may be placed between the emitter layer and base layer, with the same or different composition from either the emitter or the base layer. The intrinsic layer may function to suppress minority-carrier recombination in the space-charge region. Similarly, either the base layer or emitter layer may also be intrinsic or not-intentionally-doped (“ND”) over part or all of its thickness.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaINaS, GaInPAs, AlGaAs, AlinAs, AlInPAs, GaAsSb, GaAsSb, AlInSb, GalnSb, AlGaInSb, AlN, GaN, InN, GaInN, AlGaInN, GaInNAs, AlGaInNAs, ZnSSe, CdSSe, and similar materials, and still fall within the spirit of the present invention.

Thus, while the description of the semiconductor device described in the present disclosure has focused primarily on solar cells or photovoltaic devices, persons skilled in the art know that other optoelectronic devices, such as thermophotovoltaic (TPV) cells, photodetectors and light-emitting diodes (LEDS), are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand, LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, from the forgoing others can, by applying current knowledge, readily adapt the present invention for various applications. Such adaptions should and are intended to be comprehended within the meaning and range of equivalence of the following claims.

21. An arrangement comprising:
a III-V compound semiconductor multijunction solar cell including two mosaic portions arranged adjacent to one another in a rectangular frame deployed on outer space;
a body composed of cerium doped borosilicate glass disposed above and adjacent to the solar cell;
the glass having a composition adopted for space operations in low earth orbit at least 200 km from the surface of the earth with an operating temperature from 50° to 70° C.; and
an array of geometrical structures disposed on the light receiving or top surface of the body including a base and an apex, each structure being laser etched on the body and disposed adjacent to one another and forming a plurality of vias on the top surface of the body that are specifically computed and designed to have a size and shape that reflects and transmits incoming light in the wavelength range of 5 to 50 micros so as to change the index of refraction in the glass body and thereby increase the emissivity and IR transmissivity of the top surface of the body from 50% IR reflectivity to less than 10% IR reflectivity at least at one predetermined wavelength and functioning to reduce the retention of heat in the body caused by the generation of heat in the solar cell during illumination and operation of the solar cell, and thereby result in an operating temperature decrease in excess of 5° to 7° C. of the solar cell, and consequentially greater efficiency of the solar cell at such lower temperature.

22. An arrangement as defined in claim 21, wherein the base is polygonal in shape and has a width in a range of 5 to 50 microns, and the distance between the base and the apex is in a range of 5 to 300 microns, wherein the apex is a point or a small area forming the top of each of the geometrical structures.

23. An arrangement as defined in claim 21, wherein the base and the apex are connected by a single planar surface.

24. An arrangement as defined in claim 21, wherein the body is flat and rectangular and approximately 4 mils in thickness and the glass is cerium doped.

25. An arrangement as defined in claim 21, wherein the ration between the width of the base and the height of the geometric structure is in the range of 1:1 to 1:6.

26. An arrangement as defined in claim 21, wherein the ration between the width of the base and the height of the geometric structure is 1:3.

27. An arrangement as defined in claim 21, wherein the base is square or a hexagon in shape with a width of approximately 20 microns.

28. An arrangement as defined in claim 21, wherein the increase in IR transmissivity results in an operating temperature decrease in excess of 5° C. to 7° C., and thereby an increase in solar cell efficiency of at least 0.5%.

29. An arrangement as defined in claim 21, wherein the glass has a peak or spike in its IR transmissivity at a wavelength of approximately 9 microns, or 22 microns, or both.

30. An arrangement as defined in claim 29, wherein the IR reflectivity of a specimen flat glass at a wavelength of approximately 9 microns is in excess of 50%, and the IR reflectivity of a glass with the array of geometrical structure as computed and designed and laser etched on the top surface of the glass as set forth above is less than 10%.

31. An arrangement as defined in claim 21, wherein the size and shape of the geometric structures are designed to change or minimize the reststrahlen effect so as to improve emissivity.
